(19) United States
(12) Patent Application Publication
(10) Pub. No.: US 2010/0051971 A1
(43) Pub. Date: Mar. 4, 2010

(54) HIGH EFFICIENCY LIGHT EMITTING ARTICLES AND METHODS OF FORMING THE SAME

(76) Inventors: Andrew J. Ouderkirk, Singapore (SG); Catherine A. Leatherdale, Woodbury, MN (US)

Correspondence Address: 3M INNOVATIVE PROPERTIES COMPANY, PO BOX 33427, ST. PAUL, MN, 55133-3427, US

(21) Appl. No.: 12/515,402

(22) PCT Filed: Nov. 15, 2007
(86) PCT No.: PCT/US07/84829

§ 371 Date: May 18, 2009

Related U.S. Application Data
(60) Provisional application No. 60/866,261, filed on Nov. 17, 2006.

(51) Int. Cl. H01L 33/00; H01L 21/28; H01L 21/50

(52) U.S. Cl. 257/88; 257/99; 438/29; 438/27; 257/E33.058; 257/E33.067; 257/E21.158

(57) ABSTRACT

A light emitting article (100) is disclosed and includes a light emitting diode (110) having a p-n junction, a light emitting surface (111), and a patterned electrode (130). An extractor (140) having a light input surface (141) is optically coupled to the light emitting surface forming a light emitting interface (145). The electrode is at least partially formed within the light emitting surface and between the p-n junction and the extractor.

### RELATED APPLICATIONS

This application claims the benefit of U.S. Provisional Patent Application No. 60/866,261, filed Nov. 17, 2006, the disclosure of which is incorporated by reference herein in its entirety.

### BACKGROUND

The present disclosure relates generally to high efficiency light emitting articles and methods of forming the same.

Light emitting diodes (LEDs) have the inherent potential to provide brightness, output, and operational lifetime that would compete with conventional light sources. However, the external efficiency of these devices is often poor because light within only a small range of angles can escape from the high refractive index semiconductor material forming the LED.

The efficiency of the LED can be increased by attaching a high refractive index optical element to the surface of the semiconductor material. A high refractive index optical element can increase the range of angles that light can escape from the surface of the semiconductor material. The optical element can be suitably shaped such that light efficiently escapes from the LED. However, the optical element needs to be optically coupled to the surface of the semiconductor material for efficient light extraction to occur. Electrodes on the surface of the semiconductor material can hinder the optical coupling of the optical element and the surface of the semiconductor material.

### SUMMARY

The present disclosure relates generally to high efficiency light emitting articles and methods of forming the same. In particular, the present disclosure relates to light emitting articles that have an electrode that is at least partially disposed within the surface of the light emitting article. These electrodes facilitate optical coupling of the surface of the light emitting article with an optical element or extractor.

In one exemplary implementation, a light emitting article includes a light emitting diode having a p-n junction, a light emitting surface and a patterned electrode. An extractor having a light input surface is optically coupled to the light emitting surface forming a light emitting interface. The electrode is at least partially disposed within the light emitting surface and between the p-n junction and the extractor.

In another exemplary implementation, an array of light emitting articles includes a plurality of light emitting diodes, optically coupled to a plurality of extractors. Each light emitting diode includes a p-n junction, a light emitting surface and a patterned electrode. Each extractor has a light input surface optically coupled to the corresponding light emitting surface. At least selected patterned electrodes are at least partially disposed within the corresponding light emitting surface and between the corresponding p-n junction and the corresponding extractor.

In a further exemplary implementation, a method of forming a light emitting article includes providing a light emitting diode having a p-n junction, a light emitting surface, and a patterned electrode at least partially disposed within the light emitting surface, and optically coupling a light input surface of an extractor to the light emitting surface. The patterned electrode is at least partially disposed between the p-n junction and the extractor.

In a further exemplary implementation, a method of forming an array of light emitting articles includes providing an array light emitting diodes, where each light emitting diode includes a p-n junction, a light emitting surface, and a patterned electrode at least partially disposed within the light emitting surface, and optically coupling an array of extractor light input surfaces to the array of light emitting diodes. At least selected patterned electrodes are at least partially disposed between corresponding p-n junctions and corresponding extractors.

These and other aspects of the methods and articles according to the subject disclosure will become readily apparent to those of ordinary skill in the art from the following detailed description together with the drawings.

### BRIEF DESCRIPTION OF THE DRAWINGS

The disclosure may be more completely understood in consideration of the following detailed description of various embodiments of the disclosure in connection with the accompanying drawings, in which:

FIG. 1 is a schematic cross-sectional side elevation view of an exemplary light emitting article;

FIGS. 2A-2C are illustrative electrode patterns;

FIG. 3 is a schematic cross-sectional side elevation view of an exemplary array of light emitting articles;

FIG. 4 is a block diagram illustrating steps in manufacturing a light emitting article;

FIGS. 5A-5C are schematic cross-sectional side elevation views of a light emitting article made according to the steps shown in FIG. 4; and

FIG. 6 is a schematic cross-sectional side elevation view of another exemplary light emitting article.

While the disclosure is amenable to various modifications and alternate forms, specifics thereof have been shown by way of example in the drawings and will be described in detail. It should be understood, however, that the intention is not to limit the disclosure to the particular embodiments described. On the contrary, the intention is to cover all modifications, equivalents, and alternatives falling within the spirit and scope of the disclosure. Sizes of various elements in the drawings are approximate and many not be to scale.

### DETAILED DESCRIPTION

The present disclosure relates generally to high efficiency light emitting articles and methods of forming the same. In particular, the present disclosure relates to light emitting articles that have an electrode that is at least partially disposed within the surface of the light emitting die or diode. These electrodes facilitate optical coupling of the surface of the light emitting die or diode with an optical element or extractor. In many embodiments, the electrode is a patterned electrode in the surface of the light emitting die or diode to provide uniform current across the surface of the light emitting die or diode. This patterned electrode allows a large fraction of the surface of the light emitting die or diode to be unobstructed.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

The recitation of numerical ranges by endpoints includes all numbers subsumed within that range (e.g. 1 to 5 includes 1, 1.5, 2, 2.75, 3, 3.80, 4, and 5) and any range within that range.

As used in this specification and the appended claims, the singular forms “a”, “an”, and “the” encompass embodiments having plural referents, unless the content clearly dictates otherwise. As used in this specification and the appended claims, the term “or” is generally employed in its sense including “and/or” unless the content clearly dictates otherwise.

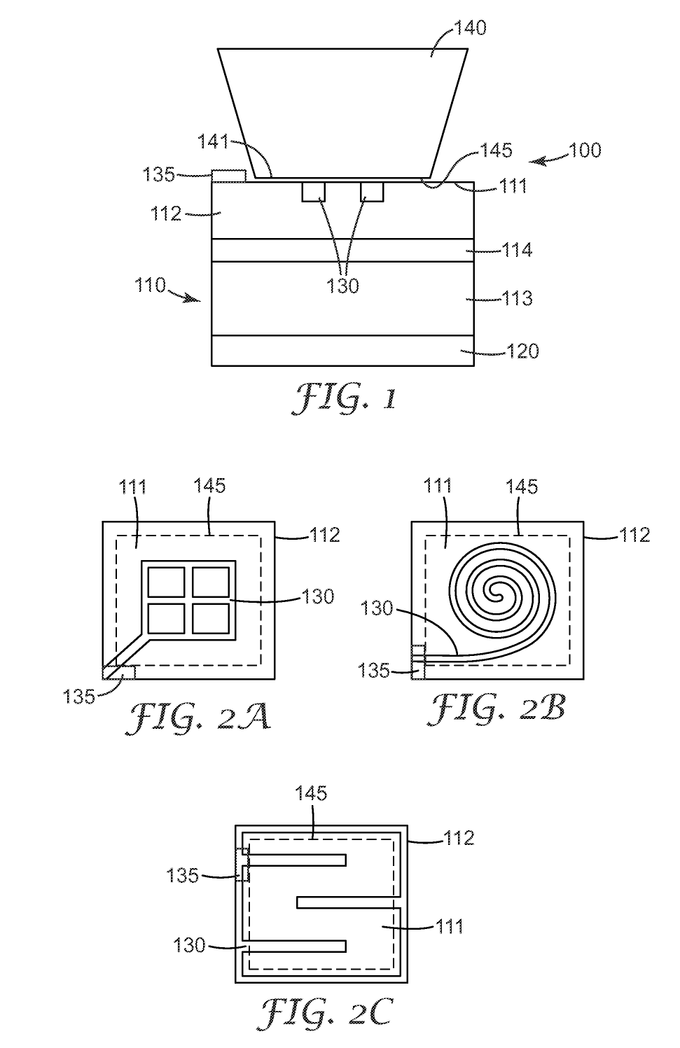

FIG. 1 is a schematic cross-sectional side elevation view of an exemplary light emitting article 100. The light emitting article 100 includes a light emitting die or diode 110 optically coupled to an optical element or extractor 140. The extractor 140 includes a light input surface 141 that is optically coupled to a light emitting surface 111 of the light emitting die or diode 110. The interface between the light input surface 141 and the light emitting surface 111 is a light emitting interface 145. The patterned electrode 130 is connected to one or more bonding pads 135 that are not in the light emitting interface 145.

The extractor 140 is considered optically coupled to the light emitting surface 111 when a minimum gap, defined by the distance between the two surfaces (141 and 111), is no greater than the evanescent wave. In many embodiments, the gap is an air gap having a thickness of less than 100 nm, or 50 nm, or 25 nm. In addition, the gap is substantially uniform over the area of contact between the light emitting surface 111 and the light input surface 141 (i.e. the light emitting interface 145) and that the light emitting surface 111 and the light input surface 141 both have a roughness of less than 20 nm, or less than 10 nm, or less than 5 nm. In case of a finite gap, optical coupling can be achieved or enhanced by adding an optically conducting layer between the light emitting surface 111 and the light input surface 141. In some embodiments, the optically conducting layer can be an optically conducting bonding layer to bond the light emitting surface 111 to the light input surface 141. The optically conducting bonding layer can be any suitable bonding agent that transmits light, including, for example, a transparent adhesive layer, inorganic thin films, fusable glass frit or other similar bonding agents. Additional examples, of bonded configurations are described, for example, in U.S. Patent Publication No. 2002/0030194, which is incorporated herein to the extent it does not conflict with the present disclosure. In other embodiments, the extractor 140 is optically coupled to the light emitting surface 111 in a non-bonded configuration as described in U.S. Patent Publication No. 2006/0091784. Optically conducting layers can include index matching oils and other liquids or gels with similar optical properties.

The light emitting die or diode 110 can include a plurality or stack of layers. The stack includes semiconductor layers and an active region, capable of emitting light. The light emitting die or diode 110 includes a first semiconductor layer 113 of n-type conductivity (n-layer) and a second semiconductor layer 112 of p-type conductivity (p-layer). Semiconductor layers 113 and 112 are electrically coupled to active region 114. Active region 114 is, for example, a p-n junction associated with the interface of layers 113 and 112. Alternatively, active region or p-n junction 114 includes one or more semiconductor layers that are doped n-type or p-type or are undoped. Active region or p-n junction 114 can also include quantum wells. First contact or electrode (p-electrode) 130 and second contact or electrode (n-electrode) 120 are electrically coupled to semiconductor layers 112 and 113, respectively. Active region or p-n junction 114 emits light upon application of a suitable voltage across electrodes 130 and 120. In alternative implementations, the conductivity types of layers 113 and 112 are reversed. That is, layer 113 is a p-type layer, electrode 120 is a p-electrode, layer 112 is an n-type layer, and electrode 130 is an n-electrode. In another alternative implementation, the bonding pads for both the n-electrode and the p-electrode may be contacted from the light emitting side of the stack of semiconductor layers. The stack may also include buffer layers, cladding layers, bonding layers, conductive or non-conductive substrates such as is known in the art.

Semiconductor layers 113 and 112 and active region or n-p junction 114 can be formed from Group III-V semiconductors including but not limited to AlN, AlP, AlAs, AlSb, GaN, GaP, GaAs, GaSb, InN, InP, InAs, InSb, Group II-VI semiconductors including but not limited to ZnS, ZnSe, CdSe, CdTe, Group IV semiconductors including but not limited to Ge, Si, SiC, and mixtures or alloys thereof. These semiconductors have indices of refraction ranging from about 2.4 to about 4.1 at the typical emission wavelengths of light emitting articles in which they are present. For example, III-Nitride semiconductors such as GaN have refractive indices of about 2.4 at 500 nm, and III-Phosphide semiconductors such as InGaP have refractive indices of about 3.6 to about 3.7 at 600 nm.

Electrodes 130 and 120 are, in one implementation, metal contacts formed from one or more layers of metals including but not limited to gold, silver, nickel, aluminum, titanium, chromium, platinum, palladium, rhodium, rhenium, ruthenium, tungsten, and mixtures or alloys thereof. In another implementation, one or both of electrodes 130 and 120 are formed from transparent conductors such as indium tin oxide, zinc oxide, and oxidized metal alloys such as described by Song et al., “Formation of low resistance and transparent ohmic contacts to p-type GaN using Ni—Mg solid solution,” Applied Physics Letters, 83(17):3513-3315 (2003).

The electrode 130 disposed between the extractor 140 (described below) and the n-p junction 114 is a patterned electrode. This patterned electrode 130 is at least partially disposed within the light emitting surface 111 and semiconductor layer 112. In many embodiments, the patterned electrode 130 and the light emitting surface 111 form a coplanar surface. In some embodiments, at least a portion of the patterned electrode 130 is entirely below the light emitting surface 111 such that the patterned electrode top surface is below the light emitting surface 111, however a portion of this electrode top surface is still coplanar with the light emitting surface 111 (such as underfilling a trench). At least a portion of the patterned electrode 130 extends beyond or outside the light emitting interface 145 to allow electrical coupling with an electrical source (not shown). Thus, the patterned electrode 130 in FIG. 1 extends out of the page further than the light emitting interface 145.

The patterned electrode 130 can have any useful configuration within the light emitting surface 111 and semiconductor layer 112. The patterned electrode 130 provides generally uniform current distribution to the n-p junction 114 while at the same time allows a large fraction of the light emitting surface 111 to be unobstructed by a normally opaque electrode. The patterned electrode 130 can be defined by any useful pattern. Conventional electrode design rules and several useful electrode patterns are described in U.S. Pat. No. 6,307,218. Patterned electrode 130 can also function as a wire grid polarizer as described in U.S. Patent Publication No. 2006/0091412. In an alternative embodiment, the patterned electrode 130 may include periodic or quasi-periodic microstructures such that surface plasmon polariton modes supported at the interface between the semiconductor layer and the metal patterned electrode are substantially scattered into light that propagates out of the plane of the semiconductor layer as described in U.S. Patent Publication NO. 2005/0269578. For example, the patterned electrode may comprise a square or triangular lattice of holes as described in U.S. Patent Publication No. 2006/0226429.

The patterned electrode 130 is electrically connected to one or more bonding pads 135 that remain exposed when the extractor is optically coupled to the light emitting surface. The bonding pads 135 are typically thicker than the patterned electrode 130 and are suitable for wire bonding, e.g., ball bonding or wedge bonding, or for soldering, for attaching with a conducting medium. Manufacturing constraints generally dictate the size of the bonding pads 135 to be about ˜0.075×10⁻³ to 0.2×10⁻³ cm².

FIGS. 2A-2C are top views of the light emitting article shown in FIG. 1 and illustrate several useful electrode patterns including, for example, a spiral and an interdigitated pattern. These views further illustrate that a portion of the patterned electrode 130 extends beyond the light emitting interface 145.

The extractor 140 is an optical element that is transparent and preferably has a high refractive index. Suitable materials for the extractor 140 include, for example, inorganic materials such as high index glasses (e.g., Schott glass type LASF35, available from Schott North America, Inc., Elmsford, N.Y. under the trade name LASF35) and ceramics (e.g., sapphire, zinc oxide, zirconia, diamond, and silicon carbide). Sapphire, zinc oxide, diamond, and silicon carbide are particularly useful since these materials also have a relatively high thermal conductivity (0.2-5.0 W/cm K). Other useful glasses include novel aluminate and titanate glasses such as those described in U.S. patent application Ser. No. 11/381,518 (Leatherdale et al.), entitled LED EXTRACTOR COMPOSED OF HIGH INDEX GLASS. High index polymers or nanoparticle filled polymers are also contemplated. Suitable polymers can be thermosetting or thermoplastic. Thermoplastic polymers can include, for example, polycarbonate and cyclic olefin polymers. Thermosetting polymers can include, for example, acrylics, epoxy, silicones, etc. Suitable nanoparticles include zirconia, titania, zinc oxide, and zinc sulfide.

The extractor 140 is shown having a diverging form; however, the extractor 140 can have any useful shape such as, for example, diverging, converging (e.g., pyramidal), or other light-redirecting shape such as lens. Converging extractors are described, e.g., in U.S. patent application Ser. No. 11/381,324 (Leatherdale et al.), entitled LED PACKAGE WITH CONVERGING OPTICAL ELEMENT. Converging extractors have at least one converging side, a base, and an apex, the apex disposed at least partially over the base and having a surface area smaller than that of the base, and the at least one converging side converging from the base towards the apex. The shape of the converging extractor can be pyramidal, polyhedral, wedge-like, cone-like, etc., or some combination thereof. The base can have any shape, e.g., square, circular, symmetrical, non-symmetrical, regular, or irregular. The apex may be a point, a line, or a flat or rounded surface, and it resides over the base either centered or skewed away from the center of the base. For a converging extractor, the base is typically disposed adjacent and generally parallel to the LED die. Also, the base and the LED die may be substantially matched in size, or the base can be smaller or larger than the LED die. Diverging extractors are described, e.g., in U.S. Patent Publication No. 2006/0091784, entitled LED PACKAGE WITH NON-BONDED OPTICAL ELEMENT. A diverging extractor has at least one diverging side, an input surface, and an output surface that is larger than an input surface. Diverging extractors are generally shaped in the form of a taper. As for converging extractors, the input surface of a diverging extractor is typically disposed closest and generally parallel to the LED die. Also, the input surface and the LED die may be substantially matched in size, or the input surface can be smaller or larger than the LED die. Other examples of diverging extractors are described in U.S. Pat. No. 7,009,213 B2 and U.S. Pat. No. 6,679,621 B2.

The index of refraction of the extractor 140 (nₒ) is preferably similar to the index of the light emitting surface 111 (nₑ). In many embodiments, the difference between the two is no greater than 0.2 (|nₒ−nₑ|≦0.2). In some embodiments, the index of refraction of the extractor 140 (nₒ) is equal to the index of the light emitting surface 111 (nₑ).

Although the figures illustrate specific light emitting article structures, the present disclosure is independent of the structure and number of semiconductor layers in the light emitting article 100 and of the detailed structure of active region or n-p junction 114. Also, the light emitting article 100 can include, for example, transparent substrates and superstrates not illustrated in FIG. 1. Further, dimensions of the various elements of the light emitting article 100 illustrated in the various figures are not to scale.

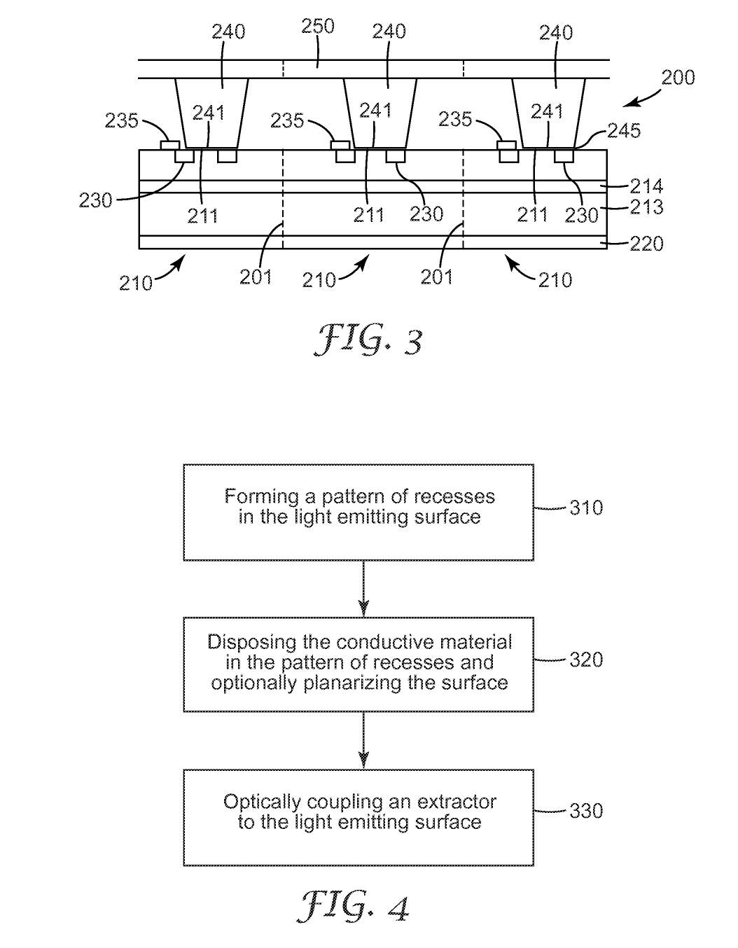

FIG. 3 is a schematic cross-sectional side elevation view of an exemplary array of light emitting articles 200. The array of light emitting articles 200 includes a plurality of light emitting dies or diodes 210 optically coupled to an array of optical elements or extractors 240. The term “array” refers to a plurality of joined or interconnected articles.

As shown in FIG. 3, the array of light emitting dies or diodes 210 are connected by a common substrate such as, for example, a semiconductor wafer. The array of extractors 240 are connected by a common substrate such as, for example, a substrate layer 250. Forming a plurality of light emitting articles 200 by optically coupling an array of dies 210 with an array of extractors 240 offers a number of benefits such as, for example, ease of manufacture of a large number of light emitting articles 200.

The plurality of extractors 240 each include a light input surface 241 that is optically coupled to a corresponding light emitting surface 211 of the corresponding light emitting die or diode 210. Each interface between the light input surface 241 and the corresponding light emitting surface 211 is a light emitting interface 245.

Each light emitting die or diode 210 includes a plurality or stack of layers. The stack includes semiconductor layers and an active region capable of emitting light. Each light emitting die or diode 210 includes a first semiconductor layer 213, as described above and a second semiconductor layer 212, as described above. Semiconductor layers 213 and 212 are electrically coupled to active region 214 or p-n junction 214, as described above. First contact or electrode 230 and second contact or electrode 220 are electrically coupled to semiconductor layers 212 and 213, respectively. A bonding pad 235 is in electrical contact with the patterned electrode 230 in a region of the light emitting surface 211 not covered by the extractor 240.

The electrode 230 disposed between the extractor 240 and the n-p junction 214 is a patterned electrode, as described above. This patterned electrode 230 is at least partially disposed within the light emitting surface 211 and semiconductor layer 212, as described above.

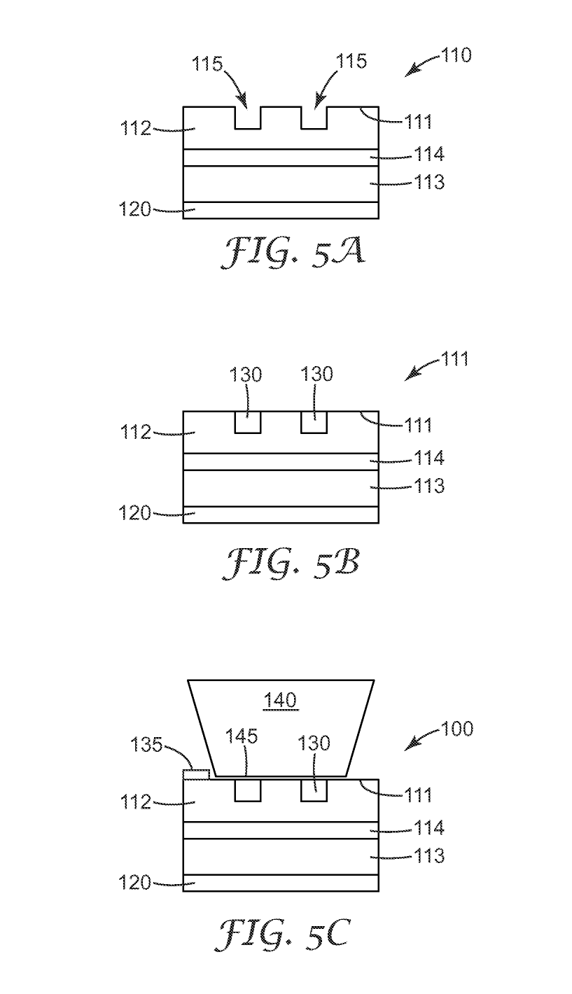

FIGS. 5A-5C are schematic cross-sectional side elevation views of a light emitting article made according to the steps shown in FIG. 4. Step 310 of FIG. 4 and the corresponding FIG. 5A show forming a pattern of recesses 115 in the light emitting surface 111. The light emitting die or diode 110 elements are described above in relation to FIG. 1.

The pattern of recesses 115 can be formed by any useful method such as, for example, mechanical ablation, laser ablation, etching, photolithography, or nanoimprint lithography. Suitable means of etching to form the recesses 115 includes, for example, reactive ion etching and inductively coupled reactive ion etching.

Step 320 of FIG. 4 and the corresponding FIG. 5B show disposing a conductive material in the pattern of recesses 115 to form the patterned electrode 130 that is at least partially disposed within the light emitting surface 111. The illustrated embodiment shows that the patterned electrode 130 and the light emitting surface 111 forms a coplanar surface where the patterned electrode 130 is substantially disposed within the semiconductor layer 112 and below the light emitting surface 111.

The conductive material can be disposed within the pattern of recesses 115 in any manner such as, for example, electroless metal deposition, physical vapor deposition, chemical vapor deposition, metal plating, and combinations thereof. In some embodiments, conductive material is disposed within the pattern of recesses 115 and forming a conductive layer (not shown) on the light emitting surface 111, and then removing the conductive layer, leaving the patterned electrode 130. The pattern of recesses 115 can be metallized by one or more metal layers. In one exemplary embodiment, patterned electrode for III-nitride devices can include titanium under aluminum for an n-layer semiconductor, and palladium under aluminum under gold for a p-layer.

Once the pattern of recesses 115 is filled with conductive material forming a patterned electrode 130, the light emitting surface 111 and/or the patterned electrode 130 can optionally be planarized by any one or more combination of techniques. These techniques include, for example, chemical mechanical polishing, abrasive slurry polishing, and fixed abrasive polishing. These techniques provide a light emitting surface 111 and/or the patterned electrode 130 having a roughness of less than 20 nm, as described above.

Step 330 of FIG. 4 and the corresponding FIG. 5C show optically coupling a light input surface 145 of an extractor 140 to the light emitting surface 111. Optically coupling can be achieved in any useful manner, as described above.

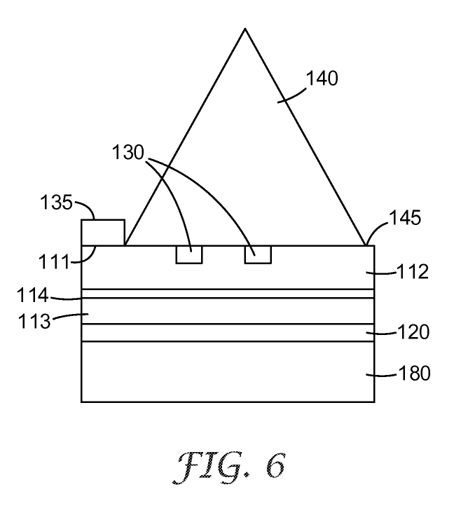

Exemplary light emitting articles include so-called “metal bonded” or thin film LEDs consisting of semiconductor layers which have been removed from their growth substrate and bonded to a conductive carrier using eutectic metal bonding or other wafer bonding approaches. FIG. 6 shows a stack of III-nitride semiconductor layers 112, 113, 114 bonded to a conductive carrier 180 with an intervening metal reflector and metal bonding layer 120. The p-layer 113 is adjacent the metal bonding layer 120. The active region 114 is separated from the metal reflector 120 by a distance of about 0.5λₙ, and about 0.9λₙ where λₙ is the wavelength of radiation emitted from the active region 114. The n-layer 112 has a pattern of recesses filled with one or more metal layers forming a patterned electrode 130 within the n-layer 112. The patterned electrode 130 is electrically connected to one or more bonding pads 135. The n-layer 112 may be substantially thicker than the p-layer 113. An extractor 140 with refractive index equal to the refractive index of the emitting surface 111 is optically coupled to the light emitting surface 111 along a light emitting interface 145.

Returning to FIG. 3, an array of light emitting articles 200 can be formed as described above for forming a single light emitting article 100, by providing a plurality of light emitting dies or diodes 210 in wafer form, forming the plurality of patterned recesses within the dies 210, disposing conductive material in at least selected patterned recesses to form the patterned electrodes 230, optionally planarizing the plurality of light emitting surfaces 211 and optically coupling an array of extractors 240 to the array of dies 210, as described above. The array of light emitting articles 200 can optionally be singulated along area 201 by any useful method such as, for example, abrasive sawing, laser scribing, and wet or dry etching.

Illustrative embodiments of this disclosure are discussed and reference has been made to possible variations within the scope of this disclosure. These and other variations and modifications in the disclosure will be apparent to those skilled in the art without departing from the scope of the disclosure, and it should be understood that this disclosure is not limited to the illustrative embodiments set forth herein. Accordingly, the disclosure is to be limited only by the claims provided below.

1. A light emitting article comprising:
a light emitting diode comprising a p-n junction, a light emitting surface, and a patterned electrode; and
an extractor having a light input surface optically coupled to the light emitting surface forming a light emitting interface;
wherein the patterned electrode is at least partially disposed within the light emitting surface and between the p-n junction and the extractor.

2. A light emitting article according to claim 1, wherein the light emitting surface is an n-electrode or p-electrode.

3. A light emitting article according to claim 1, wherein the light emitting surface and the patterned electrode form a coplanar surface.

4. A light emitting article according to claim 1, wherein the light emitting surface has a roughness of less than 20 nm.

5. A light emitting article according to claim 1, wherein the patterned electrode has an interdigitated pattern or spiral pattern.

6. A light emitting article according to claim 1, wherein at least a portion of the patterned electrode extends beyond the light emitting interface.

7. A light emitting article according to any of claim 1, further comprising a gap defined by the distance between the light emitting surface and the extractor, the gap being less than 100 nm.

8. A light emitting article according to claim 1, further comprising an optically conducting bonding layer bonding the light emitting surface to the extractor.

9. A method of forming a light emitting article comprising:
providing a light emitting diode comprising a p-n junction, a light emitting surface, and a patterned electrode at least partially disposed within the light emitting surface; and
optically coupling a light input surface of an extractor to the light emitting surface, wherein the patterned electrode is at least partially disposed between the p-n junction and the extractor.

10. A method according to claim 9, further comprising:
forming a pattern of recesses in the light emitting surface; and
disposing a conductive material in the pattern of recesses to form the patterned electrode that is at least partially disposed within the light emitting surface.

11. A method according to claim 9, further comprising:
planarizing the patterned electrode and the light emitting surface after the disposing step to form a coplanar light emitting surface having a surface roughness of less than 20 nm.

12. A method according to claim 9, wherein the optically coupling step comprises bonding the light input surface to the light emitting surface with an optically conducting bonding layer.

13. An array of light emitting articles comprising:
a plurality of light emitting diodes, each light emitting diode comprising a p-n junction, a light emitting surface, and a patterned electrode; and
a plurality of extractors, each extractor having a light input surface optically coupled to the corresponding light emitting surface;
wherein at least selected patterned electrodes are at least partially disposed within the corresponding light emitting surface and between the corresponding p-n junction and the corresponding extractor.

14. An array of light emitting articles according to claim 13, wherein at least selected light emitting surfaces and patterned electrodes form a coplanar surface.

15. A method of forming an array of light emitting articles comprising:
providing an array light emitting diodes, wherein each light emitting diode comprises a p-n junction, a light emitting surface, and a patterned electrode at least partially disposed within the light emitting surface; and
optically coupling an array of extractor light input surfaces to the array of light emitting diodes, wherein at least selected patterned electrodes are at least partially disposed between corresponding p-n junctions and corresponding extractors.

16. A method according to claim 15, further comprising:
forming a pattern of recesses in at least selected light emitting surfaces; and
disposing a conductive material in the pattern of recesses to form the patterned electrode that is at least partially disposed within at least selected light emitting surfaces.

17. A method according to claim 16, further comprising:
planarizing at least selected electrodes and light emitting surfaces after the disposing step
to form coplanar light emitting surfaces having a surface roughness of less than 20 nm.

18. A method according to claim 15, wherein the providing step comprises providing an array light emitting diodes in wafer form.

19. A method according to claim 15, further comprising singulating the array of light emitting articles to form a plurality of light emitting articles.

20. A method according to claim 15, wherein the optically coupling step comprises bonding the array of light input surfaces to the array of light emitting surfaces with an optically conducting bonding layer.
